(19) United States
(12) Patent Application Publication
(10) Pub. No.: US 2013/0264587 A1
(43) Pub. Date: Oct. 10, 2013

(54) STACKED LED DEVICE USING OXIDE BONDING

(71) Applicant: Yuan-Hsiao Chang, Taipei City (TW)

(72) Inventor: Yuan-Hsiao Chang, Taipei City (TW)

(73) Assignee: PHOSTEK, INC., Taipei City (TW)

(21) Appl. No.: 13/438,886

(22) Filed: Apr. 4, 2012

(51) Int. Cl. H01L 27/15; H01L 33/42; H01L 33/08

(52) U.S. Cl. 257/88; 438/28; 257/E33.012; 257/E33.064; 257/E27.121

(57) ABSTRACT

A semiconductor light emitting device includes a substrate, a first epitaxial structure, a first substantially transparent conducting layer, a second epitaxial structure, a second substantially transparent conducting layer, and a substantially transparent insulating layer. The first epitaxial structure is over the substrate and includes a first doped layer, a first light emitting layer, and a second doped layer. The first substantially transparent conducting layer is coupled to the second doped layer. The second epitaxial structure includes a third doped layer, a second light emitting layer, and a fourth doped layer. The second substantially transparent conducting layer is coupled to the fourth doped layer. The substantially transparent insulating layer is between the first substantially transparent conducting layer and the second substantially transparent conducting layer.

### BACKGROUND

1. Field of the Invention

The present invention relates to a semiconductor light emitting component, and more particularly to a light emitting diode (LED) module and a method for manufacturing the LED module.

2. Description of Related Art

U.S. Pat. No. 7,575,340 to Kung et al. (“Kung '340”), which is incorporated by reference as if fully set forth herein, describes conventional light projectors using gas discharge lamps as the optical engine of the projectors along with their deficiencies and how light source systems using light-emitting diode (LED) modules as the optical engine can overcome some of the problems. Conventional projectors (optical systems) that use gas discharge lamp light sources may be expensive and have short service lives. Gas discharge lamp light sources may also emit ultraviolet light, which requires isolation of the gas discharge lamp to inhibit damage due to the ultraviolet light. Gas discharge lamps are also not typically thought of as being environmentally friendly or a “green product” because of the energy usage of the lamps and the use of mercury in the lamps.

To overcome the problems with gas discharge lamps, Kung '340 describes light source system 10 using three LED modules 12, 14, 16 as the optical engine, shown in FIG. 1. The light source system of Kung '340, however, uses three separate, stand-alone sets of LED modules (e.g., one set each of red, blue, and green LED modules). The light from the three separate sets of LED modules is combined to provide the resultant light emitted from the light source system (e.g., light projector system). The use of multiple sets of LED modules and corresponding components (e.g., a diode lens cap and a primary lens unit) may, however, be bulky and more expensive. Thus, there is a need to reduce the size of the optical engine and potentially lower the cost for producing the light source system.

### SUMMARY

In certain embodiments, a semiconductor light emitting device includes a substrate, a first epitaxial structure, a first substantially transparent conducting layer, a second epitaxial structure, a second substantially transparent conducting layer, and a substantially transparent insulating layer. The first epitaxial structure is over the substrate and includes a first doped layer, a first light emitting layer, and a second doped layer. The first substantially transparent conducting layer is coupled to the second doped layer. The second epitaxial structure includes a third doped layer, a second light emitting layer, and a fourth doped layer. The second substantially transparent conducting layer is coupled to the fourth doped layer. The substantially transparent insulating layer is between the first substantially transparent conducting layer and the second substantially transparent conducting layer.

In certain embodiments, a method for forming a semiconductor light emitting device includes providing a first epitaxial structure over a first substrate. The first epitaxial structure includes a first doped layer, a first light emitting layer, and a second doped layer. A first substantially transparent conducting layer is coupled to the second doped layer. A second epitaxial structure is provided over a second substrate. The second epitaxial structure includes a third doped layer, a second light emitting layer, and a fourth doped layer. A second substantially transparent conducting layer is coupled to the fourth doped layer. The first substantially transparent conducting layer of the first epitaxial structure is bonded to the second substantially transparent conducting layer of the second epitaxial structure with a substantially transparent insulating layer.

In certain embodiments, a light emitting diode array includes two or more interconnected light emitting diode modules formed on a base material. Each light emitting diode module may include a substrate, a first epitaxial structure, a first substantially transparent conducting layer, a second epitaxial structure, a second substantially transparent conducting layer, and a substantially transparent insulating layer. The first epitaxial structure is over the substrate and includes a first doped layer, a first light emitting layer, and a second doped layer. The first substantially transparent conducting layer is coupled to the second doped layer. The second epitaxial structure includes a third doped layer, a second light emitting layer, and a fourth doped layer. The second substantially transparent conducting layer is coupled to the fourth doped layer. The substantially transparent insulating layer is between the first substantially transparent conducting layer and the second substantially transparent conducting layer.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 depicts a prior art light source system using three LED modules as an optical engine.

FIG. 2 depicts a side-view representation of an embodiment of a light emitting diode (LED).

FIG. 3 depicts a side-view representation of an embodiment of a bottom LED and a top LED before bonding to form the stacked LED module.

FIG. 4 depicts a side-view representation of an embodiment of the bottom LED bonded to the top LED.

FIG. 5 depicts a side-view representation of an embodiment with a temporary substrate removed from the bottom LED.

FIG. 6 depicts a side-view representation of an embodiment with a permanent substrate coupled to the bottom LED.

FIG. 7 depicts a side-view representation of an embodiment with a temporary substrate removed from the top LED to form the stacked LED module.

FIG. 8 depicts a side-view representation of an embodiment with electrodes formed on the stacked LED module.

FIG. 9 depicts a side-view representation of an embodiment of the bottom LED bonded to the top LED with the bottom LED formed on a patterned substrate.

FIG. 10 depicts a side-view representation of an embodiment with a temporary substrate removed from the bottom LED and the bottom surface of the bottom LED being patterned.

FIG. 11 depicts a side-view representation of an embodiment with a permanent substrate coupled to the patterned bottom surface of the bottom LED.

FIG. 12 depicts an embodiment of an LED array with two stacked LED modules on a base material.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

In the context of this patent, the term “coupled” means either a direct connection or an indirect connection (e.g., one or more intervening connections) between one or more objects or components.

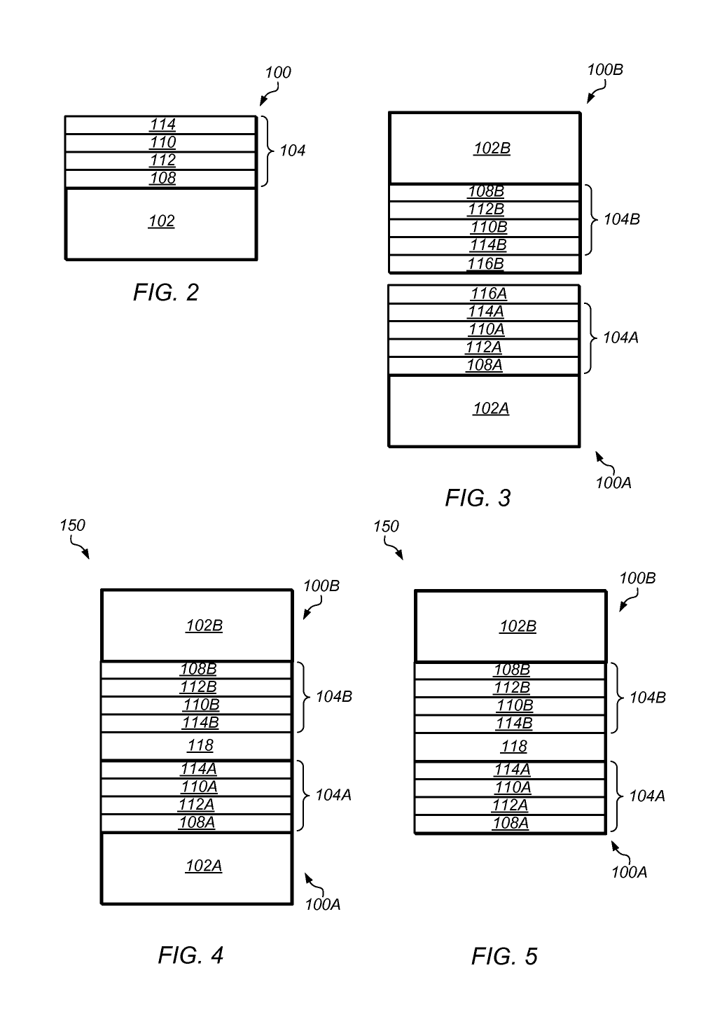

FIG. 2 depicts a side-view representation of an embodiment of light emitting diode (LED) 100. LED 100 includes epitaxial structure 104 on substrate 102. In certain embodiments, epitaxial structure 104 is grown from substrate 102 by a thin film deposition process (e.g., an epitaxial growth process). In certain embodiments, substrate 102 is made of a material such as sapphire or SiC. With sapphire or SiC, epitaxial growth of group-III nitride (e.g., GaN, InGaN, AlGaN, AlInGaN) can be achieved on substrate 102. In some embodiments, substrate 102 is a patterned substrate (e.g., a patterned sapphire substrate). In some embodiments, substrate 102 includes a reflective layer on the upper surface of the substrate. The reflective layer may include a distributed Bragg reflector (DBR), an omni-directional reflector (ODR), silver, aluminum, titanium, and/or other reflective metals.

In certain embodiments, during the epitaxy growth process, group-III nitride material is epitaxially grown up from substrate 102 to form n-doped layer 108 and p-doped layer 110. In certain embodiments, light emitting portion 112 is between n-doped layer 108 and p-doped layer 110. In some embodiments, epitaxial structure 104 includes undoped layer (not shown) between substrate 102 and n-doped layer 108.

In certain embodiments, conducting layer 114 is formed on top of p-doped layer 110. Conducting layer 114 may be formed on top of p-doped layer 110 using, for example, a deposition process. In certain embodiments, conducting layer 114 is a substantially transparent conducting layer. Conducting layer 114 may include, for example, indium tin oxide (ITO). In certain embodiments, conducting layer 114 provides current spreading for p-doped layer 110.

When electrical energy is applied to epitaxial structure 104, light emitting portion 112 at junction of n-doped layer 108 and p-doped layer 110 generates an electron-hole capture phenomenon. As a result, the electrons of light emitting portion 112 will fall to a lower energy level and release energy with a photon mode. In certain embodiments, light emitting portion 112 is a single quantum well (SQW) or a multiple quantum well (MQW) structure capable of restricting a spatial movement of the electrons and the holes. Thus, a collision probability of the electrons and the holes is increased so that the electron-hole capture phenomenon occurs easily, thereby enhancing light emitting efficiency.

When a voltage is applied between n-doped layer 108 and p-doped layer 110, an electric current flows between electrodes coupled to the n-doped layer and the p-doped layer through epitaxial substrate 102 and is horizontally distributed in epitaxial structure 104. Thus, a number of photons are generated by a photoelectric effect in epitaxial structure 104. LED 100 emits light from epitaxial structure 104 due to the horizontally distributed electric current.

In certain embodiments described herein, two LEDs 100 may be combined (e.g., stacked) to form an LED module emitting light beams with the same wavelengths. In certain embodiments described herein, two LEDs 100 may be combined (e.g., stacked) to form an LED module emitting two separate light beams with different wavelengths. For example, a green light emitting LED may be stacked with a blue light emitting LED in a single LED module such that the LED emits the green light beam separately from the blue light beam. FIGS. 3-8 depict various steps in an embodiment of a process for forming a stacked LED module with two LEDs 100. FIG. 3 depicts a side-view representation of an embodiment of bottom LED 100A and top LED 100B before bonding to form the stacked LED module. In certain embodiments, bottom LED 100A includes substrate 102A and epitaxial structure 104A. Epitaxial structure 104A includes n-doped layer 108A, p-doped layer 110A, light emitting layer 112A, and conducting layer 114A. In certain embodiments, top LED 100B includes substrate 102B and epitaxial structure 104B. Epitaxial structure 104B includes n-doped layer 108B, p-doped layer 110B, light emitting layer 112B, and conducting layer 114B.

In certain embodiments, substrates 102A, 102B are sapphire substrates. In certain embodiments, substrates 102A, 102B are temporary substrates. In certain embodiments, light emitting layer 112A is a green light emitting layer and light emitting layer 112B is a blue light emitting layer. Thus, in certain embodiments, bottom LED 100A is a green light emitting LED and top LED 100B is a blue light emitting LED. As shown in FIG. 3, top LED 100B may be flipped vertically with respect to bottom LED 100A. Flipping top LED 100B allows bottom LED 100A and top LED 100B to be coupled (e.g., bonded) in a p-side to p-side coupling process (e.g., p-doped layer 110A in bottom LED 100A faces p-doped layer 110B in top LED 100B and the p-doped layers are the nearest doped layers in the stacked LED module).

In certain embodiments, bottom LED 100A and top LED 100B are coupled (e.g., bonded) using insulating layers (e.g., oxide layers) formed on either or both of the LEDs. For example, insulating layer 116A may be formed (e.g., deposited) on the upper surface of bottom LED 100A (e.g., insulating layer 116A is formed on top of conducting layer 114A) and insulating layer 116B may be formed on the lower surface (as pictured in FIG. 3) of top LED 100B (e.g., insulating layer 116B is formed on top of conducting layer 114B). In certain embodiments, insulating layer 116A and/or insulating layer 116B are substantially transparent insulating layers. Insulating layer 116A and/or insulating layer 116B may include, for example, solid oxides such as silicon oxide (e.g., silicon dioxide). Insulating layer 116A and/or insulating layer 116B may be formed using a deposition process such as a chemical vapor deposition (CVD) process. For example, insulating layer 116A and/or insulating layer 116B may be formed using a plasma-enhanced chemical vapor deposition (PECVD) process or low-pressure chemical vapor deposition (LPCVD) process.

In certain embodiments, bottom LED 100A is coupled to top LED 100B using a bonding process that bonds insulating layer 116A to insulating layer 116B to form insulated bonding layer 118 between the bottom LED and the top LED in stacked LED module 150, as shown in FIG. 4 (e.g., the insulating layers combine to form the insulated bonding layer). Insulating layer 116A may be bonded to insulating layer 116B using processes known in the art including, but not limited to, anodic bonding processes, plasma treatment bonding processes, or chemical surface treatment and bonding processes. In some embodiments, only one insulating layer is used for coupling bottom LED 100A to top LED 100B. For example, insulating layer 116A on bottom LED 100A may be bonded to conducting layer 114B on top LED 100B or insulating layer 116B on top LED 100B may be bonded to conducting layer 114A on bottom LED 100A. The insulating layer of an LED may be bonded to the conducting layer of the other LED using, for example, bonding processes known in the art for bonding silicon oxide to ITO.

In some embodiments, insulating layer 116A and/or insulating layer 116B include oxide formed from a spin-on-glass (SOG) coating. SOG is a chemical fluid dissolved in a highly volatile organic solution or a film spin-coated by this chemical fluid. Typical silicon compounds of SOG solution are [RnSi(OH)₄₋ₙ] and [RnSi(OC₂H₅)₄₋ₙ]. When SOG is treated with heat after being spin-coated, a dehydration contraction reaction occurs and a film comprised mainly of silicon dioxide is formed. The use of SOG coatings in the stacked LED module may, however, have certain disadvantages. One disadvantage of SOG is the large volume shrinkage during the curing process. As a result of the volume shrinkage, the SOG layer may retain high stress and crack easily during curing and further handling. The cracking of the SOG layer may cause a serious contamination problem for the fabrication process. The cracking problem may sometimes be avoided by the application of only a thin layer of SOG (e.g., 1000-2000 Å of the silicate SOG material). In order to reach a final thickness of several thousand angstrom of the SOG layer, several thinner layers of the silicate SOG material are deposited. It has been found, however, that even by depositing multiple thinner layers of SOG (e.g., in as many as four separate deposition steps) the final SOG layer obtained may still have a cracking problem during curing or subsequent processing.

In certain embodiments, the bonding surfaces for bottom LED 100A and top LED 100B are relatively flat. For example, certain bonding processes may have maximum roughness requirements ensure proper bonding between the two surfaces. In certain embodiments, each of the bonding surfaces may have a surface roughness of at most about 2 μm.

As shown in FIG. 4, the presence of insulated bonding layer 118 inhibits electrical shorting between conducting layers 114A, 114B when bottom LED 100A is coupled to top LED 100B in stacked LED module 150. Following bonding of top LED 100B to bottom LED 100A, substrate 102A may be removed from the bottom LED, as shown in FIG. 5. Substrate 102A may be removed using, for example, a laser lift-off (LLO) process, an acid etching process, or another suitable etching process.

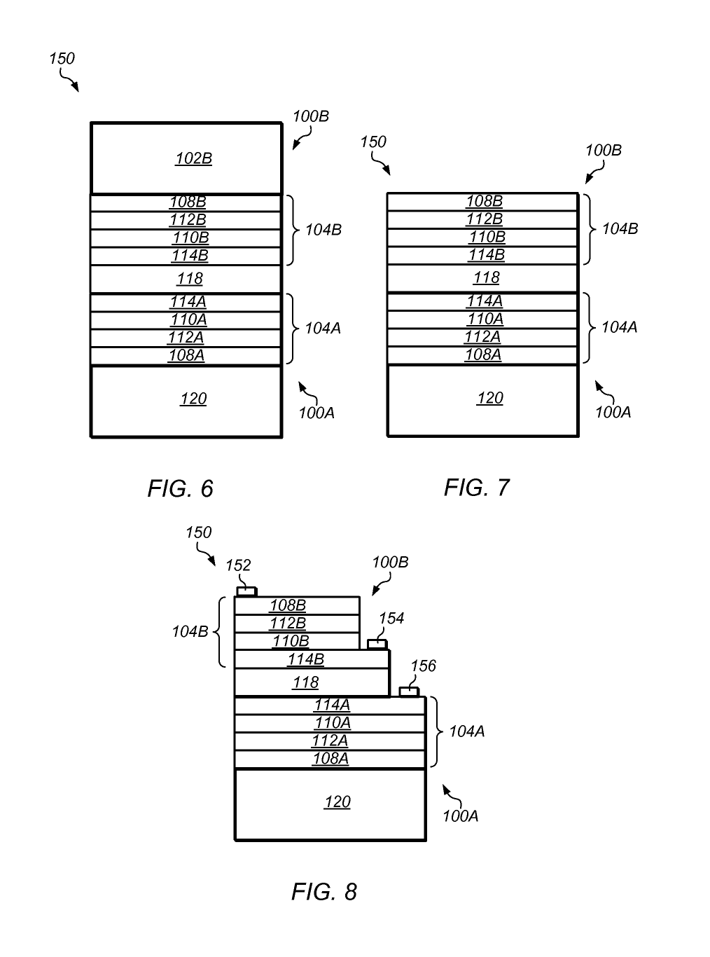

Following removal of substrate 102A, substrate 120 may be coupled (e.g., bonded) to n-doped layer 108A or an undoped layer (not shown) of bottom LED 100A, as shown in FIG. 6. Substrate 120 may be a permanent substrate for stacked LED module 150. In certain embodiments, substrate 120 is a silicon or a metal substrate. Substrate 120 may be coupled to bottom LED 100A using, for example, bonding with an adhesive layer (e.g., epoxy glue, wax, photoresist, monomer, polymer, orbenzocyclobutene (BCB)), eutectic bonding, or metal bonding. In some embodiments, substrate 120 is formed in-situ on bottom LED 100A using, for example, a deposition process. In some embodiments, substrate 120 includes a reflective layer on its upper surface. The reflective layer may include a distributed Bragg reflector (DBR), an omni-directional reflector (ODR), silver, aluminum, titanium, and/or other reflective metals.

Following coupling substrate 120 to bottom LED 100A, substrate 102B may be removed from top LED 100B, as shown in FIG. 7. Substrate 102B may be removed using, for example, a LLO process, an acid etching process, or another suitable etching process. After substrate 102B is removed, electrodes 152, 154, 156 are formed on stacked LED module 150, as shown in FIG. 8. Electrodes 152, 154, 156 may be, for example, bonding pads for connection to doped layers in stacked LED modules 150. Electrodes 152, 154, 156 may be formed using one or more etch processes (e.g., inductively coupled plasma (ICP) etches) followed by one or more electrode material (e.g., metal) deposition steps. For example, one or more etching processes may be used to remove portions of layers in top LED 100B and insulated bonding layer 118 to form pads for contacting the electrodes to p-doped layers 110A, 110B (via conducting layers 114A, 114B, respectively) and n-doped layer 108B. In certain embodiments, n-doped layer 108A is contacted through interconnection with substrate 120 if the substrate is silicon or metal since n-doped layer 108A and the substrate are in ohmic contact.

Following the etching process(es), electrode material may be formed (deposited) on the pads such that electrodes 152, 154, 156 are in ohmic contact with their respective underlying layers. For example, electrode 152 is in ohmic contact with n-doped layer 108B, electrode 154 is in ohmic contact with conductive layer 114B, and electrode 156 is in ohmic contact with conductive layer 114A. Because conductive layers 114A, 114B are in ohmic contact with p-doped layers 110A, 110B, respectively, electrodes 154, 156 are electrically connected to their respective p-doped layers through the conductive layers. In certain embodiments, electrodes 152, 154 provide electrical energy to top LED 100B and electrode 156 and substrate 120 provide electrical energy to bottom LED 100A.

In certain embodiments, electrodes 152, 154, 156 are formed such that the electrodes face the same direction, as shown in FIG. 8. For example, the top surfaces of electrodes 152, 154, 156 may face away from substrate 120 (e.g., the contact surfaces of the electrodes are on the upper surface of stacked LED module 150). With the top (exposed) surfaces of electrodes 152, 154, 156 facing away from substrate 120, connections (e.g., bonds) may be made to the electrodes from the same side (e.g., the upper side) of stacked LED module 150. Making connections to electrodes 152, 154, 156 on the upper surface of stacked LED module 150 may reduce the size of an optical device derived from the stacked LED module.

In certain embodiments, electrodes 152, 154 are physically and electrically isolated from electrode 156 and substrate 120 to allow for independent control of bottom LED 100A and top LED 100B. Electrically isolating the electrodes for each of bottom LED 100A and top LED 100B allows for independent control of the epitaxial structures of the bottom and top LEDs. For example, epitaxial structure 104A of bottom LED 100A may be biased independently from epitaxial structure 104B of top LED 100B. Independent biasing of epitaxial structure 104A and epitaxial structure 104B provides independent control of light emitting layers 112A, 112B. Thus, in certain embodiments, light emitting layer 112A and light emitting layer 112B emit different wavelengths of light that are independently controllable. In certain embodiments, light emitting layer 112A emits light with a longer wavelength than light emitted from light emitting layer 112B. For example, light emitting layer 112A may emit green light and be independently controlled from light emitting layer 112B that emits blue light.

Because bottom LED 100A and top LED 100B can be controlled independently, stacked LED module 150 can emit light in a range of wavelengths between the wavelength emitted by the bottom LED and the wavelength emitted by the top LED. For example, at any point during use, stacked LED module 150 may emit light at the wavelength of bottom LED 100A, the wavelength of top LED 100B, or a combination of the wavelengths of the bottom LED and the top LED depending on the biases applied to the bottom LED and the top LED.

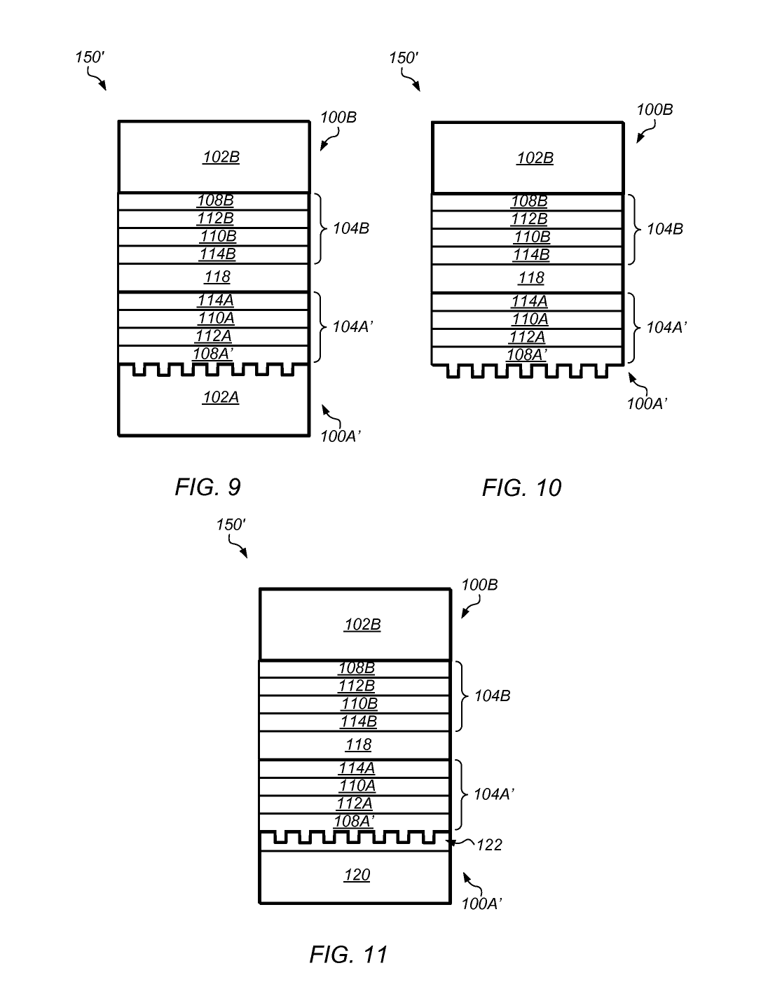

In some embodiments, the bottom surface of n-doped layer 108A or an undoped layer in bottom LED 100A is patterned. The bottom surface of n-doped layer 108A or the undoped layer may be patterned by forming epitaxial structure 104A on a patterned substrate or the n-doped layer or the undoped layer may be patterned after removal of substrate 102A. FIGS. 9-11 depict modifications to the steps depicted in FIGS. 4-6 for an alternative embodiment of a process for forming a stacked LED module with a patterned bottom n-doped layer. FIG. 9 depicts bottom LED 100A′ coupled to top LED 100B with insulated bonding layer 118 in stacked LED module 150′. As shown in FIG. 9, epitaxial structure 104A′ has been formed on patterned substrate 102A′. Thus, n-doped layer 108A′ is formed in a pattern correlated to the pattern on substrate 102A′.

FIG. 10 depicts stacked LED module 150′ after removal of substrate 102A′. Substrate 102A′ may be removed by, for example, an LLO process. The patterned bottom surface of n-doped layer 108A′ or the undoped layer is exposed after removal of substrate 102A′. In some embodiments, patterned n-doped layer 108A′ or the undoped layer is formed by patterning of the bottom surface of the n-doped layer after removal of a normal, flat substrate (e.g., substrate 102A depicted in FIG. 4). Thus, patterned n-doped layer 108A′ (or undoped layer), as shown in FIG. 10, is formed using transfer of the pattern from a patterned substrate (shown in FIG. 9) or patterning of the exposed layer.

Patterned n-doped layer 108A′ may then be coupled (e.g., bonded) to substrate 120, as shown in FIG. 11. In certain embodiments, patterned n-doped layer 108A′ or the undoped layer is bonded to substrate 120 with adhesive layer 122. Adhesive layer 122 may be used with patterned n-doped layer 108A′ as the adhesive layer may provide a stronger bond than other types of bonding (e.g., metal bonding). Subsequent steps to form stacked LED module 150′ after coupling substrate 120 to patterned n-doped layer 108A′ may be similar to those steps depicted in FIGS. 7-8 for the embodiment of stacked LED module 150. A stacked LED module with patterned n-doped layer 108A′ or undoped layer, formed from the embodiment of stacked LED module 150′ depicted in FIG. 11, may have increased light extraction as compared to stacked LED module 150, depicted in FIG. 8.

While FIGS. 3-11 depict various steps in embodiments of processes for forming stacked LED module 150 or stacked LED module 150′ with two LEDs, it is to be understood that one or more of the steps depicted and described herein may be used in a process to form multiple stacked LED modules on a single substrate or multiple substrates. For example, the steps depicted and described herein may be used in a wafer-to-wafer bonding process with multiple bottom LEDs formed on a first wafer bonded to multiple top LEDs formed on a second wafer.

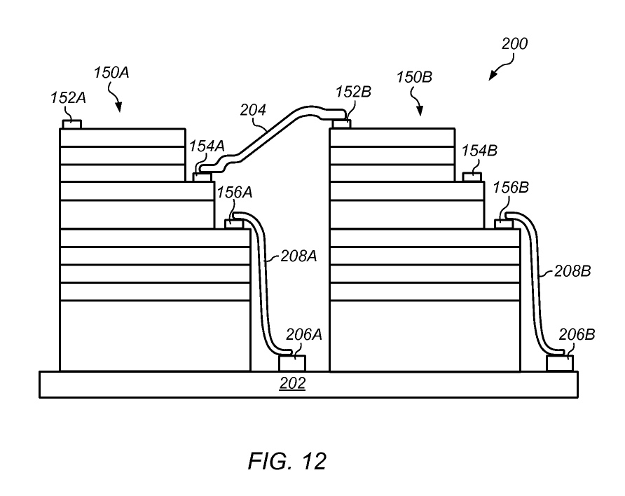

In certain embodiments, two or more stacked LED modules 150 are interconnected in an LED array. For example, a plurality of stacked LED modules may be interconnected on a single base material. FIG. 12 depicts an embodiment of LED array 200 with two stacked LED modules 150A, 150B on base material 202. In certain embodiments, base material 202 is a patterned base material such as a printed wiring board or printed circuit board. Stacked LED modules 150A, 150B may be bonded to base material 202 such that the bottom LEDs of the stacked LED modules are in ohmic contact with the base material or at least part of a wiring pattern formed on the base material. For example, stacked LED modules 150A, 150B may be bonded to base material 202 using glue bonding, eutectic bonding, or metal bonding.

In certain embodiments, electrode 154A of stacked LED module 150A is interconnected with electrode 152B of stacked LED module 150B. For example, electrode 154A may be interconnected with electrode 152B via interconnect 204. Interconnect 204 may be, for example, a patterned interconnect or a wire bond between the electrodes. Interconnection of electrode 154A to electrode 152B electrically connects the top LED of stacked LED module 150A with the top LED of stacked LED module 150B. The top LEDs of either stacked LED module 150A or stacked LED module 150B may be interconnected to additional stacked LED modules on base material 202 and/or to one or more power supplies that provide power to the top LEDs of the stacked LED modules.

The bottom LED of stacked LED module 150A may be interconnected with base material 202 via interconnection of electrode 156A with electrode 206A on the base material. Electrode 206A may be, for example, a silicon or metal electrode formed on base material 202. Electrode 206A may be in ohmic contact with at least a portion of base material 202 (e.g., a wiring pattern formed on the base material). Electrode 156A and electrode 206A may be interconnected via interconnect 208A. Interconnect 208A may be, for example, a patterned interconnect or a wire bond between the electrodes.

The bottom LED of stacked LED module 150B may be interconnected with base material 202 via interconnection of electrode 156B with electrode 206B on the base material. Electrode 206B may be, for example, a silicon or metal electrode formed on base material 202. Electrode 206B may be in ohmic contact with at least a portion of base material 202 (e.g., a wiring pattern formed on the base material). Electrode 156B and electrode 206B may be interconnected via interconnect 208B. Interconnect 208B may be, for example, a patterned interconnect or a wire bond between the electrodes.

The bottom LED of stacked LED module 150A and the bottom LED of stacked LED module 150B may be electrically connected in series or in parallel through base material 202. For example, base material 202 may have a wiring pattern that provides either series or parallel interconnection between the bottom LEDs of the stacked LED modules. Base material 202 may also provide interconnection to one or more power supplies to provide power to the bottom LEDs.

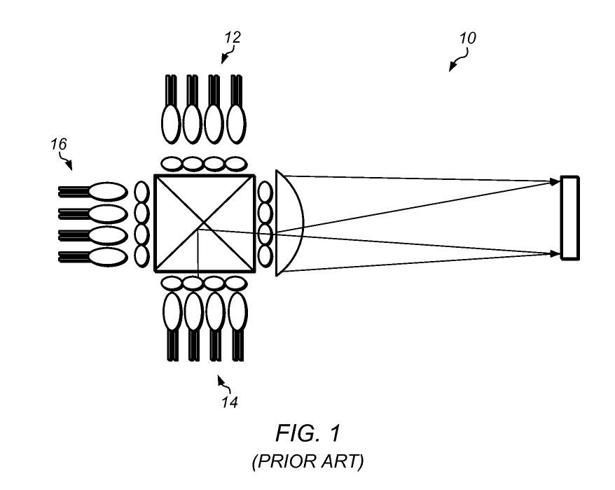

In some embodiments, one or more stacked LED modules 150, 150′ and/or LED array 200 are used in a light projector system. For example, stacked LED modules 150, 150′ and/or LED array 200 may be used as the optical engine, or as part of the optical engine, in a light projector (source) system similar to light source system 10, depicted in FIG. 1. Using stacked LED modules 150, 150′ and/or LED array 200 in the light projector system may reduce the size of the system by combining two different wavelength light sources into a single set of LED modules (e.g., stacked LED modules 150). Combining the two different wavelength light sources and reducing the size of the light projector system may potentially lower the cost for making and operating the light projector system.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A semiconductor light emitting device, comprising:
a substrate;
a first epitaxial structure over the substrate, the first epitaxial structure comprising a first doped layer, a first light emitting layer, and a second doped layer;
a first substantially transparent conducting layer coupled to the second doped layer;
a second epitaxial structure, the second epitaxial structure comprising a third doped layer, a second light emitting layer, and a fourth doped layer;
a second substantially transparent conducting layer coupled to the fourth doped layer; and
a substantially transparent insulating layer between the first substantially transparent conducting layer and the second substantially transparent conducting layer.

2. The device of claim 1, wherein the first doped layer comprises a first dopant type and the second doped layer comprises a second dopant type, and wherein the third doped layer comprises the first dopant type and the fourth doped layer comprises the second dopant type.

3. The device of claim 1, wherein the substantially transparent insulating layer comprises silicon oxide, the first substantially transparent conducting layer and/or the second substantially transparent conducting layer comprise indium tin oxide.

4. The device of claim 1, wherein a surface of the first substantially transparent conducting layer coupled to the substantially transparent insulating layer and a surface of the second substantially transparent conducting layer coupled to the substantially transparent insulating layer comprise flat surfaces.

5. The device of claim 1, wherein the first dopant type comprises n-type dopant and the second dopant type comprises p-type dopant.

6. The device of claim 1, wherein the first epitaxial structure is biased independently of the second epitaxial structure.

7. The device of claim 1, wherein the first light emitting layer is independently controlled from the second light emitting layer.

8. The device of claim 1, wherein the substrate comprises a patterned substrate.

9. The device of claim 1, wherein a surface of the first epitaxial structure facing the substrate is patterned.

10. A method for forming a semiconductor light emitting device, comprising:
providing a first epitaxial structure over a first substrate, the first epitaxial structure comprising a first doped layer, a first light emitting layer, and a second doped layer;
coupling a first substantially transparent conducting layer to the second doped layer;
providing a second epitaxial structure over a second substrate, the second epitaxial structure comprising a third doped layer, a second light emitting layer, and a fourth doped layer;;
coupling a second substantially transparent conducting layer to the fourth doped layer; and
bonding the first substantially transparent conducting layer of the first epitaxial structure to the second substantially transparent conducting layer of the second epitaxial structure with a substantially transparent insulating layer.

11. The method of claim 10, wherein the first doped layer comprises a first dopant type and the second doped layer comprises a second dopant type, and wherein the third doped layer comprises the first dopant type and the fourth doped layer comprises the second dopant type.

12. The method of claim 10, wherein the substantially transparent insulating layer comprises silicon oxide, and wherein the first substantially transparent conducting layer and/or the second substantially transparent conducting layer comprise indium tin oxide.

13. The method of claim 10, further comprising forming at least part of the substantially transparent insulating layer on a surface of the first substantially transparent conducting layer on the first epitaxial structure prior to bonding the first substantially transparent conducting layer to the second substantially transparent conducting layer.

14. The method of claim 10, further comprising forming at least part of the substantially transparent insulating layer on a surface of the second substantially transparent conducting layer on the second epitaxial structure prior to bonding the first substantially transparent conducting layer to the second substantially transparent conducting layer.

15. The method of claim 10, wherein a surface of the first substantially transparent conducting layer coupled to the substantially transparent insulating layer and a surface of the second substantially transparent conducting layer coupled to the substantially transparent insulating layer comprise flat surfaces.

16. The method of claim 10, further comprising:
removing the first substrate from the first epitaxial structure;
bonding the first epitaxial structure to a third substrate; and
removing the second substrate from the second epitaxial structure.

17. The method of claim 10, further comprising:
forming a first electrode coupled to the third doped layer;
forming a second electrode coupled to the second substantially transparent conducting layer; and
forming a third electrode coupled to the first substantially transparent conducting layer.

18. The method of claim 10, wherein the first dopant type comprises n-type dopant and the second dopant type comprises p-type dopant.

19. The method of claim 10, wherein the first substrate comprises a patterned substrate.

20. The method of claim 10, further comprising patterning a surface of the first epitaxial structure facing the first substrate.

21. A light emitting diode array, comprising:
two or more interconnected light emitting diode modules formed on a base material, wherein each light emitting diode module comprises:
a substrate;
a first epitaxial structure over the substrate, the first epitaxial structure comprising a first doped layer, a first light emitting layer, and a second doped layer;
a first substantially transparent conducting layer coupled to the second doped layer;
a second epitaxial structure over the substrate, the second epitaxial structure comprising a third doped layer, a second light emitting layer, and a fourth doped layer;
a second substantially transparent conducting layer coupled to the fourth doped layer; and
a substantially transparent insulating layer between the first substantially transparent conducting layer and the second substantially transparent conducting layer.

22. The array of claim 21, wherein the first doped layer comprises a first dopant type and the second doped layer comprises a second dopant type, and wherein the third doped layer comprises the first dopant type and the fourth doped layer comprises the second dopant type.

23. The array of claim 21, wherein the substrate is a conductive substrate, and wherein the light emitting diode module further comprises:
a first electrode coupled to the first substantially transparent conducting layer;
a second electrode coupled to the second substantially transparent conducting layer; and
a third electrode coupled to the fourth doped layer;
wherein one of the conductive substrate and the first electrode of one light emitting diode module is coupled to one of the conductive substrate and the first electrode of an adjacent light emitting module;
wherein one of the second electrode and the third electrode of one light emitting diode module is coupled to one of the second electrode and the third electrode of an adjacent light emitting module.
